(19) United States
(12) Patent Application Publication
(10) Pub. No.: US 2014/0011373 A1
(43) Pub. Date: Jan. 9, 2014

(54) ANNEALING A SACRIFICIAL LAYER

(71) Applicants: Aravind Killampalli, Beaverton, OR (US); Charles H. Wallace, Portland, OR (US); Sridhar S. Govindaraju, Portland, OR (US)

(72) Inventors: Aravind Killampalli, Beaverton, OR (US); Charles H. Wallace, Portland, OR (US); Sridhar S. Govindaraju, Portland, OR (US)

(21) Appl. No.: 13/995,168

(22) PCT Filed: Dec. 28, 2011
(86) PCT No.: PCT/US11/67539

§ 371 Date: Sep. 20, 2013

(51) Int. Cl. H01L 21/263

(52) U.S. Cl. CPC H01L 21/2636
USPC 438/795

(57) ABSTRACT

Methods for semiconductor processing include annealing a sacrificial material to change a characteristic of the sacrificial material. Changes may include reducing line edge roughness, changing density, changing surface chemistry, or changing a dimension of patterns of the sacrificial material. At least one additional process may be included to change a layer positioned below the sacrificial material before removing all, or substantially all, of the sacrificial material.

### BACKGROUND

The present subject matter relates to semiconductor processing. More specifically, the present subject matter relates to an annealing process for modifying characteristics of a sacrificial layer in a semiconductor process.

Semiconductor devices are built in semiconductor materials, typically silicon wafers (or substrates), through a series of processes. These processes modify the silicon wafer by building, components of the semiconductor devices in the wafer using a variety of materials, including conductive materials, insulating materials, and semiconducting materials. Various materials may be deposited as layers on the silicon substrate and patterned using various lithography techniques. Current lithography techniques are reaching the limits of resolution requiring alternative methodologies to print feature sires beyond a 32 nanometer (nm) node. Examples of such alternative methodologies include double or multiple exposure techniques, self-aligned spacer double patterning and dual-tone photo-resists.

Many of the processes to build these components involve the use of thermal treatments that work to overcome the activation energies that govern the processes. These activation energies determine the rate of construction or modification of the components using the respective thermal treatment. One such thermal treatment is annealing of metallic interconnect layers on the semiconductor substrate, which may he accomplished by rapidly heating a silicon wafer to achieve target temperatures. Such annealing may be performed using various techniques including flash and laser annealing processes.

### BRIEF DESCRIPTION OF THE DRAWINGS

The accompanying drawings, which are incorporated in and constitute part of the specification, illustrate various embodiments. Together with the general description, the drawings serve to explain various principles. In the drawings:

FIG. 1A is a flow chart of an embodiment of a method including annealing a sacrificial materials.

FIG. 2A-E show cross-sectional views of a silicon substrate at various stages that may be suitable for use in an embodiment:

FIG. 3A-C show photomicrographs of a cross-section of a silicon substrate at various stages that may be suitable for use in an embodiment;

FIG. 4 shows a silicon substrate being annealed:

FIG. 5A/B show cross-sectional views of a silicon substrate after being annealed;

FIG. 6A shows a plan view and FIG. 6B shows a corresponding cross-sectional view of a silicon substrate showing various results of annealing; and

FIGS. 7A and 7B show cross-sectional views of a silicon substrate at different stages of processing after annealing the sacrificial material according to an embodiment.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures and components have been described at a relatively high-level, without detail, in order to avoid unnecessarily obscuring aspects of the present concepts. A number of descriptive terms and phrases are used in describing the various embodiments of this disclosure. These descriptive terms and phrases are used to convey a generally agreed upon meaning to those skilled in the art unless a different definition is given in this specification. Some descriptive terms and phrases are presented in the following paragraphs for clarity.

A semiconductor substrate, as the term is used herein and in the claims, may refer to a semiconductor wafer, or portion of a semiconductor wafer, such as one or more semiconductor dice. The semiconductor material may he silicon, gallium arsenide, or any other suitable semiconducting material, and the semiconductor substrate may be composed of bulk semiconductor material or may be a layer of semiconductor material on an insulating substrate such as sapphire or bulk silicon. The semiconductor substrate may include one or more layers of additional material that has been deposited or otherwise placed onto the semiconductor substrate. The additional layers may be composed of any type of material including, but not limited to, metals, metallic compounds, various oxides, various nitrides, or other conducting, semiconducting, insulating and/or photosensitive materials. Reference now is made in detail to the examples illustrated in the accompanying drawings and discussed below.

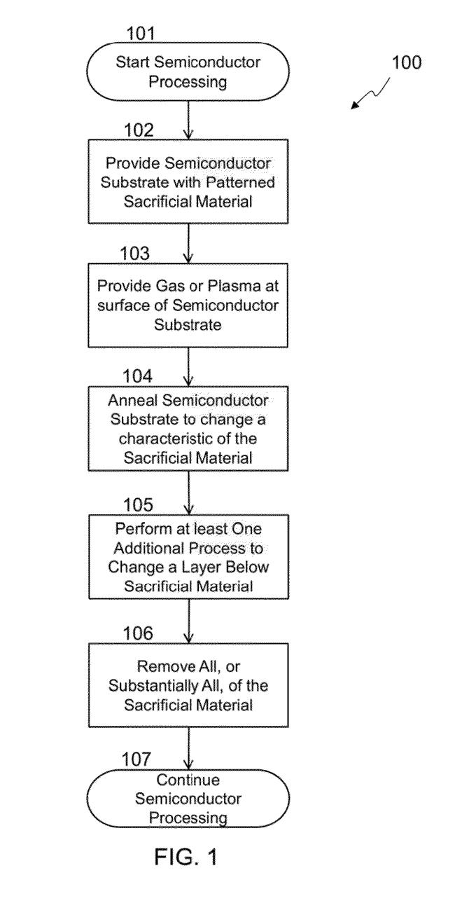

FIG. 1A is a flow chart 100 of an embodiment of a method of annealing a sacrificial material. The semiconductor processing begins at block 101. A semiconductor substrate having a sacrificial layer on a surface of the semiconductor substrate is provided at block 102. The layer may be referred to as a sacrificial layer because at least part of the layer may be removed at a later stage of the processing. In some embodiments, all, or nearly all, of the sacrificial layer may be removed at later processing stages. The sacrificial layer may be made of any type of material, depending on the embodiment, that may be referred to as the sacrificial material. The sacrificial material may, in some embodiments, be a non-metallic material such as a silicon compound, including silicon oxide, silicon nitride, or silicon oxynitride. In other embodiments, the sacrificial material may be a non-metallic compound including one or more atoms of a metallic element, such as titanium oxide or aluminum oxide. In various embodiments the sacrificial material may be another oxide, nitride or oxynitride compound or some other type of compound such as a polymer or a photosensitive material suitable for a photoresist application. In some embodiments the sacrificial material may be an organic compound, and a metallic material may be used as the sacrificial material in other embodiments.

The sacrificial material may be patterned so that only some areas of the semiconductor substrate may be covered by the sacrificial material. Various techniques may be used to pattern the sacrificial material including, but not limited to, photolithography, various types of etching, laser ablation, crystalline growth, or any other technique for creating patterns of the sacrificial material. In various embodiments, many of the patterns may create lines or other shapes having relatively straight edges, although some embodiments may include arcs or other curved edges. Although the intended shapes may be patterns with smooth edges, in actual implementations, some roughness of the edges may occur, due to various causes.

The semiconductor substrate with the patterned sacrificial material may be inserted into a chamber to allow the environment around the semiconductor substrate to be controlled. In some embodiments, the chamber may be evacuated of gas to create a near vacuum around the semiconductor substrate. In other embodiments, a gas or plasma may be provided at the surface of the semiconductor substrate in block 103. The gas may be an inert gas, such as argon, to avoid creating any chemical reactions with the sacrificial material. In other embodiments, gas may be provided to react with the sacrificial material. In at least one embodiment, the gas may be nitrogen and the sacrificial material may be an oxide, so that an oxynitride may be formed if the right conditions are provided for the chemical reaction. Other types of gases may be used for other reactions in other embodiments.

In some embodiments, a plasma may be provided at the surface of the semiconductor. The plasma may be of various compositions, but may include a similar set of elements as may be used if a gas is introduced. A plasma may be used in place of a gas for various reasons related to the particular processing techniques or processing equipment used to create the desired chemical composition at the surface of the sacrificial material.

At block 104, the semiconductor substrate is annealed to change a characteristic of the sacrificial material. The annealing may heat the semiconductor substrate to create the desired change of the characteristic. The anneal, in some embodiments, may be a sub-second anneal lasting less than about one second that may or may not be combined with a spike anneal lasting about one second, and/or a soak anneal lasting greater than about one second. Any length or time may be used for the annealing process in other embodiments but some embodiments may perform the sub-second anneal for a time period between about 1 millisecond (ms) and about 100 ms. Any technique may be used for the annealing process but in some embodiments a laser based enemy source may be used to heat the semiconductor substrate or a portion of the semiconductor substrate. In other embodiments, a flash anneal may be used to heat the semiconductor substrate using electromagnetic radiation from to bulb or other flash source. Some embodiments may use other energy sources. In some embodiments, the heat source may he directed toward the semiconductor substrate from one or more directions, such as from above and/or beneath the semiconductor substrate. In other embodiments the heat may be directed toward the semiconductor substrate omni-directionally or indirectly, to heat the semiconductor substrate evenly. In some embodiments, the energy may be directed to a portion of the semiconductor substrate.

Various characteristics of the sacrificial material may be changed by the annealing process. In some embodiments, the density of the sacrificial material may he changed. In various embodiments, a physical profile of various features of the sacrificial material may be changed, such as a thickness of the sacrificial material, a width of a patterned feature of the sacrificial material, or a length of a patterned feature of the sacrificial material. In other embodiments, a chemical composition of the surface of the sacrificial material may be changed by the annealing process.

After the sacrificial material has been annealed, at least one additional process may be performed to change a layer positioned below the sacrificial material at block 105. The use of the term “below” herein and in the claims is used to indicate that the layer is positioned between the base material of the semiconductor substrate and the sacrificial material. In some embodiments, the layer changed by the at least one additional process may be in contact with the sacrificial material, which may be directly on top of the layer to be changed. In other embodiments, other layers may be interposed between the sacrificial material and the layer to be changed by the at least one additional process. The layer to be changed may be any type of material, including a metallic layer, a polysilicon layer, a gate oxide layer, a doped semiconductor layer, or any other layer of the semiconductor substrate.

The at least one additional process may be any type of process capable of changing the layer positioned below the sacrificial material. In some embodiments, the at least one additional process may include an etching process to each away areas of the layer positioned below the sacrificial material at places not covered by the sacrificial material. In other embodiments, the at least one additional process may include ion implantation processes or other processes to change the chemical composition of the layer positioned below the sacrificial layer at places not covered by the sacrificial material. Any semiconductor processing technique may be used to change any aspect of the layer positioned below the sacrificial layer. The sacrificial material may or ma not be affected by the at least one additional process.

At block 106, all, or substantially all, of the sacrificial material is removed. The purpose of the sacrificial layer is to facilitate the processing of other layers of the semiconductor substrate, and the sacrificial material is not intended to be left in place in a final semiconductor device. Nevertheless, in some embodiments, the sacrificial material may not be completely removed, The reasons for not entirely removing the sacrificial material may include processing variations, details of a particular semiconducting process, or other factors. “Substantially all” may mean that about 95% or more of the sacrificial material may be removed. Another way that a sacrificial layer may be defined is material that is used to help create patterns in a layer below the sacrificial material.

Semiconductor processing may continue at block 107. The further processing may include any type and number of processes to complete the preparation of a semiconductor device such as an integrated circuit. The completed semiconductor device may be a processor, a memory or any other type of semiconductor device.

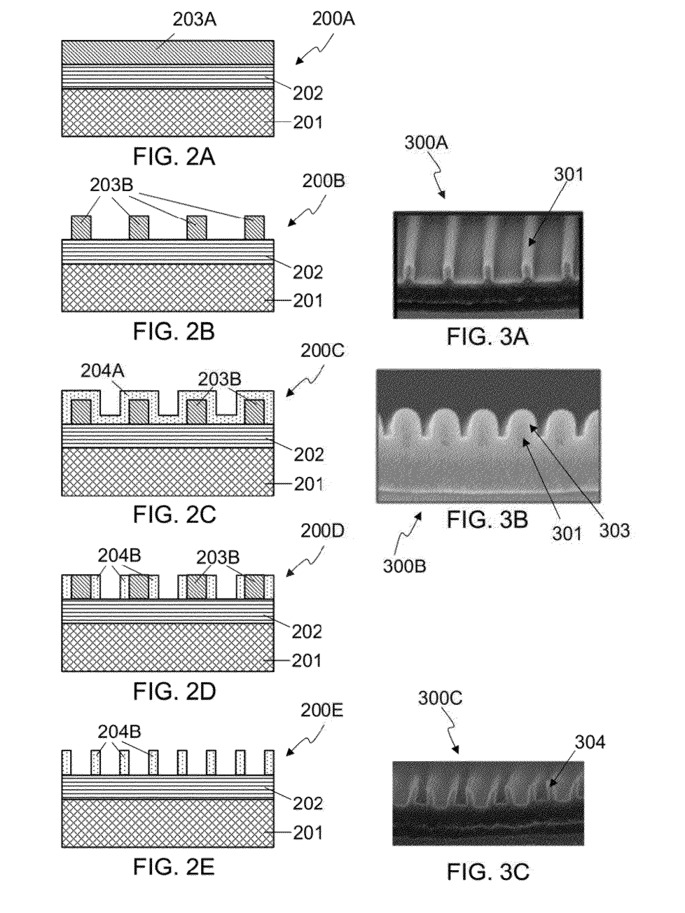

FIG. 2A-E, show cross-sectional views of a silicon substrate 200 at various stages that may be suitable for use in an embodiment. A silicon substrate 200 is shown as the semiconductor substrate for this particular embodiment but other embodiments may use any type of semiconductor substrate. Other embodiments may not include all the processes described in the discussion of FIG. 2A-E. Various embodiments miry also include processes not described in the discussion of FIG. 2A-E. The process shown by FIG. 2A-E may be referred to as spacer-based double patterning but other types of processes may be used in other embodiments.

FIG. 2A shows the base material 201 of the silicon substrate 200A and the layer 202 to be changed at a later stage of the process is shown between the photoresist layer 203A and the base material 201 which may also be referred to as being below the photoresist layer 203A. The layer 202 to be modified may be any type of material useful in the creation of a semiconductor device and the photoresist layer 203A may be a sacrificial material as described earlier. Other layers may be positioned between the base material 201 and the layer 202 to be modified and/or between the photoresist layer 203A and the layer 202 in some embodiments. FIG. 2B shows the silicon substrate 200B after the photoresist layer 203A has been patterned The patterning may be performed using any technique as described before including photo-lithography. Various features may be created in the photoresist layer 203A, such as the lines 203B shown in cross-section.

Silicon substrate 200C is shown in FIG. 2C. A layer of silicon oxide 204A or other sacrificial material has been deposited over the patterned photoresist layer including over the lines 203B. The silicon oxide 204A may be referred to as a spacer material or spacer layer. FIG. 2D shows the silicon substrate 200D after portions of the silicon oxide 204A has been removed. The portion of the silicon oxide 204A removed may be the portions that are substantially parallel to the silicon base material 201 leaving spacers 204B of silicon oxide on the sides of the photoresist lines 203B. The portions of the silicon oxide 204A may be removed using any type of process including various mechanical and/or chemical processes. Silicon substrate 200E is shown in FIG. 2E. The photoresist lines 203B have been removed leaving the spacers 204B.

The silicon substrate 200A-E may be subjected to an annealing process at any of the stages shown in FIG. 2A-E to change a characteristic of one or more sacrificial layers, as the photoresist layer 203 and/or the spacer layer 204, in various embodiments. Depending on the specifics of the particular process, one or more characteristics of one or more sacrificial layers may be changed. In some embodiments, the silicon substrate nay be subjected to an annealing process at multiple stages shown. Other embodiments may use an annealing process on a sacrificial material at other stages that may be different than those shown.

FIG. 3A-C show photomicrographs of a cross-section of a silicon substrate 300 at various stages that may he suitable for use in an embodiment. FIG. 3A shows silicon substrate 300A with photoresist lines 301. Silicon substrate 300A is comparable to silicon substrate 200B shown in FIG. 2B. FIG. 3B shows silicon substrate 300B and is comparable to silicon substrate 200C shown in FIG. 2C. Photoresist line 301 is covered wall silicon oxide 303 in FIG. 3B, FIG. 3C shows silicon substrate 300C and is comparable to silicon substrate 200E shown in FIG. 2E, FIG. 3C shows the spacers 304 that are farmed after portions of the silicon oxide 303 and the photoresist lines 301 are removed.

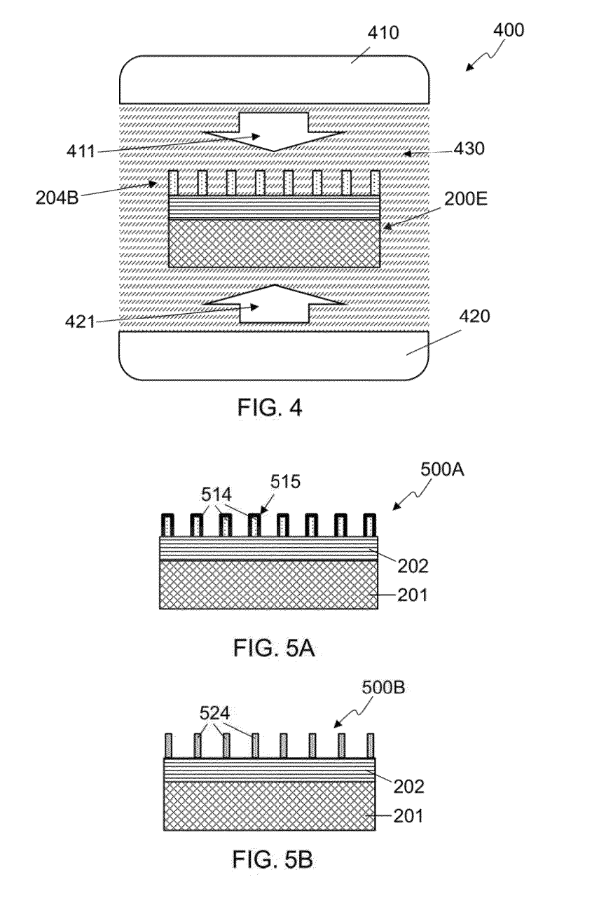

FIG. 4 shows a silicon substrate 200E be in processed using an embodiment. The substrate could be any of the silicon substrates 200A-E or a silicon substrate at some other processing stage, depending on the embodiment. The silicon substrate 200E may be placed in processing equipment 400 that may include a chamber allowing the environment around the silicon substrate 200E to be controlled. A first heat source 410 to provide energy 411 from above the silicon substrate 200E, and a second heat source 420 to provide energy 421 from beneath the silicon substrate 200E, may be included in the processing equipment 400. Providing energy from above may direct the energy 411 to the side of the silicon substrate 200E having the sacrificial material 204B. Providing energy from beneath may direct the energy 421 to the side of the silicon substrate 200E not having the sacrificial material 204B. The beat sources 410, 420 may be any type of heat source, including, but not limited to, a laser light source, and a flash lamp source. The chamber of the processing equipment 400 may be tilled with a gas or plasma, such as nitrogen gas 430, allowing the gas or plasma to be present at the surface of the silicon substrate 200E. In some embodiments, the first heat source 410 may emit energy 411 from above to anneal the silicon substrate 200E. In other embodiments, the second heat source 420 may emit energy 421 from beneath to anneal the silicon substrate 200E. In some embodiments, both the first heat source 410 and second heat source 420 may be used, in any combination over time, to anneal the silicon substrate 200E. In some embodiments, the annealing process may be a sub-second anneal, meaning that the energy is emitted only for a very short period of time less than about 1 s. Other embodiments may use a spike anneal and/or a soak anneal in combination with a sub-second anneal. Varying the duration, intensity, heat source and environment around the silicon substrate may allow various characteristics of the sacrificial material to be changed.

FIG. 5A shows silicon substrate 500A including spacers 514. Silicon substrate 500A may have been annealed in the presence of a gas or plasma and the surface chemistry of the surface 515 of the spacers 514 may have been changed by the annealing. Other embodiments may use the annealing to change the chemical composition of the sacrificial material in various ways by using various gases or plasmas provided at the surface of the silicon substrate during the annealing process and/or by varying the temperature profile of the annealing process. In the embodiment shown, the nitrogen gas 430 may react with the silicon oxide of the spacers 514 to form silicon oxynitride on the surface 515 of the spacers 514.

FIG. 5B shows silicon substrate 500B after an annealing process. The density of the spacers 524 may have been changed by the annealing process. In the embodiment shown, the spacers 524 are more dense after annealing. The density change may be due to shrinkage of the spacers in one or more dimension in some embodiments. In other embodiments, the density may he increased due to a chemical reaction during the annealing. In other embodiments, the density may be increased due to removal of moisture or other impurities in the spacers 524. Density may also be decreased in the sacrificial material by chemical reactions that occur during an anneal process which may be accompanied by a suitable gas or plasma.

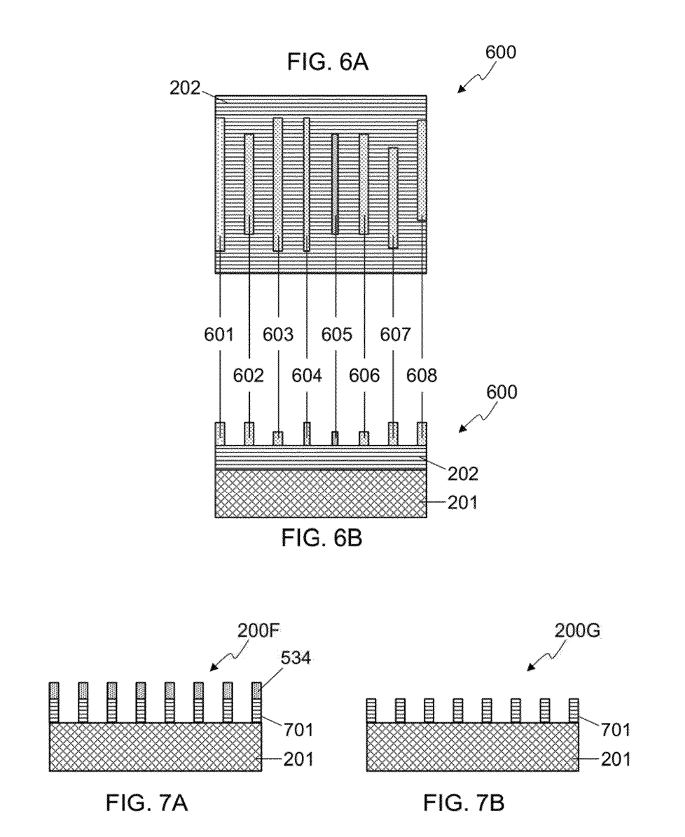

FIG. 6A shows a plan view and FIG. 6B shows a corresponding cross-sectional view of a silicon substrate 600 showing various possible results of processing using an embodiment. The various sacrificial lines 601-608 may not be created using the same annealing process but may be considered as various independent examples of changes that may be made by annealing the sacrificial material. The various lines 601-608 are shown on a single silicon substrate 600 for simplicity and easy comparison.

Line 601 may be representative of a sacrificial line before being annealed. Line 601 has a given length that may be thought of as the longest dimension of a given feature, and a given width, that may be the dimension that is perpendicular to the length in the plan view of FIG. 6A. Line 601 may also have as thickness that is the dimension that is perpendicular to the plane of the silicon substrate 600.

Lines 602-608 show various physical profiles of the sacrificial material that may be changed by annealing. Line 602 has had its length changed by annealing. Line 602 has shrunk symmetrically about its center. Line 603 has had its thickness changed by the annealing. Line 604 has had its width changed by annealing. Line 605 has had all three dimensions, thickness, length and width changed by the annealing and line 606 has had its thickness and length changed by annealing. Lines 607 and 608 have had their length changed by annealing, with line 607 primarily shrinking toward one end and line 608 primarily shrinking toward the other end. The various changes of physical profile may be created using various environmental conditions at the surface of the silicon substrate 600, varying the location of the heat source, varying the length of the heating, and/or by varying the temperature profile during the anneal.

Another characteristic of the sacrificial material that may be changed by annealing in some embodiments is the line edge roughness of the sacrificial material. Line edge roughness may be thought of as the amount of deviation from an intended geometric edge and may be measured in various ways. While there may be many methods of measuring line edge roughness, one method is to measure the width of a line of sacrificial material having a constant desired width at several places over the length of the line. The standard deviation of the measurements may be calculated and may be multiplied by a constant, such as 3, and used as a measure of the line edge roughness of the line. Line edge roughness may be affected by various factors including, but not limited to, defects in the sacrificial material, lithography errors, dust or other foreign matter, or other factors.

In one embodiment tested, line edge roughness was reduced by about 15% by annealing the sacrificial material in the embodiment tested, a standard photoresist material was deposited on the silicon substrate and patterned using standard lithography techniques with a feature size of about 45 nanometer (nm). The patterned photoresist was then implanted to harden the photoresist before being covered with a layer of silicon oxide about 10 nm thick. A test wafer was annealed after implantation, while a control wafer was not annealed. The anneal of the test wafer included a soak anneal at about 100° C. followed by a sub-second anneal directed to the top of the silicon substrate using, a flash-based energy source. The sub-second anneal had a duration of about 1.5 milliseconds (ms) with a peak temperature of about 350° C. Had the wafers been intended to produce finished product, additional process stages would have been followed, including stages to pattern layers below the sacrificial silicon oxide material, to produce semiconductor products; however, these particular wafers were removed from processing to analyze the effects of annealing.

The spacers were measured on both wafers. Measurements were taken at 64 places ever about a 500 mm length of the spacers and a standard deviation of the measurements was calculated for each wafer and multiplied by 3 as a measure of line edge roughness. The spacers of the control wafer had a line edge roughness of about 1.8 nm while the annealed wafer had a line edge roughness of about 1.5 nm showing an improvement of about 5%. This improved line edge roughness of the sacrificial material may result in improved line edge roughness of patterned features below the sacrificial layer and ma result in improved yields of the finished semiconductor products being produced. Varying various aspects of the process, such as the type, duration, direction, temperature, length, or other aspects of the anneal, may produce other changes to the sacrificial material, including even more improvement of line edge roughness and/or characteristics discussed elsewhere in this disclosure. The particular example discussed here is included only as an example of one particular embodiment and should not limit this disclosure in any way.

The various effects of annealing the sacrificial material may allow for more reliable further processing. For example, increasing the density of the sacrificial material may strengthen the sacrificial material, allowing the patterns of the sacrificial material to maintain their shape during further processing. Changes in the surface chemistry may be helpful in depositing additional layers of material. Reducing line edge roughness may help improve yield. Various changes to the sacrificial material may be desirable for a variety of reasons.

FIGS. 7A and 7B show cross-sectional views of a silicon substrate 200 at different stages of processing after annealing of the sacrificial material 534 according to an embodiment. FIG, 7A shows silicon substrate 200F that may be created by performing at least one additional process to change a layer 202 positioned below the sacrificial layer, such as the spacers 534 in the embodiment shown. The spacers 534 may have been annealed to change a characteristic of the sacrificial material of the spacers 534 before performing at least one additional process. In the embodiment shown, the at least one additional process includes an etch process that etches away areas of the layer 202 positioned below the sacrificial layer, spacers 534, at places not covered, by the sacrificial material oldie spacers 534. The etching leaves portions of the layer 202, sections 701, beneath the spacers 534. The sections 701 may have improved line edge roughness due to the annealing of the spacers 534. FIG. 7B shows the silicon substrate 200G after another process or processes remove all, or substantially all, of the sacrificial material, or spacers 534. Sections 701 remain on the base material 201 of the silicon substrate 200G although additional layers may be positioned between the portions 701 and the base material 201 in some embodiments.

Unless otherwise indicated, all numbers expressing, quantities of elements, optical characteristic properties, and so forth used in the specification and claims are to be understood as being modified in all instances by the term “about.” Accordingly, unless indicated to the contrary, the numerical parameters set forth in the preceding specification and attached claims are approximations that can vary depending upon the desired properties sought to be obtained by those skilled in the art utilizing various principles of the present disclosure. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of this disclosure are approximations, the numerical values set forth in the specific examples are reported as precisely as possible. Any numerical value, however, inherently contains certain errors necessarily resulting, from the standard deviations found in their respective testing measurements. The recitation of numerical ranges by endpoints includes all numbers subsumed Within that range (e.g. 1 to 5 includes 1, 1,5, 2, 2,75, 3, 3.80, 6, and 5).

As used in this specification and the appended claims, the singular forms “a”, “an”, and “the” include plural referents unless the content clearly dictates otherwise. Furthermore as used in this specification and the appended claims, the term “or” is generally employed in its sense including “and/or” unless the content clearly dictates otherwise. As used herein, the term “coupled” includes direct and indirect connections. Moreover, where first and second devices are coupled, intervening devices including active devices may be located there between.

The description of the various embodiments provided above is illustrative in nature and is not intended to limit this disclosure, its application, or uses. Thus, different variations beyond those described, herein are intended to be within the scope of embodiments. Such variations are not to be regarded as a departure from the intended scope of this disclosure. As such the breadth and scope of the present disclosure should not be limited by the above-described exemplary embodiments, but should be defined only in accordance with the following, claims and equivalents thereof.

What is claimed is:

1. A method comprising:
providing a semiconductor substrate having a sacrificial material;
annealing, the semiconductor substrate to clue a characteristic of the sacrificial material; and
performing at least one additional process to change a layer positioned below the sacrificial material.

2. The method of claim 1, further comprising removing all or substantially ail of the sacrificial material.

3. The method of claim 1, wherein the sacrificial material comprises photoresist material.

4. The method of claim 1, wherein the sacrificial material comprises silicon oxide.

5. The method of claim 1, wherein the sacrificial material comprises a non-metallic material.

6. The method of claim 1, wherein the sacrificial material is located on a surface of the semiconductor substrate.

7. The method of claim 1, wherein the annealing is performed using a sub-second anneal.

8. The method of claim 1, wherein the annealing is performed using a combination of a sub-second anneal and a spike anneal.

9. The method of claim 1, wherein the annealing is performed using a combination of a sub-second anneal and a soak anneal.

10. The method of claim 1, wherein the annealing comprises:
heating the semiconductor substrate from above.

11. The method of claim 1, wherein the annealing comprises:
heating the semiconductor substrate from beneath.

12. The method of claim 1, wherein the annealing is performed using a flash lamp.

13. The method of claim 1, wherein the annealing is performed using a laser.

14. The method of claim 1, wherein the characteristic of the sacrificial material that is changed by the annealing is line edge roughness.

15. The method of claim 1, wherein the characteristic of the sacrificial material that is changed by the annealing is density.

16. The method of claim 1, wherein the characteristic of the sacrificial material that is changed by the annealing is a dimension.

17. The method of claim 1, further comprising providing a gas or a plasma at a surface of the semiconductor substrate during the annealing:
wherein the characteristic of the spacer material that is changed by the annealing is a chemical composition of a surface of the spacer material.

18. The method of claim 1, wherein the at least one additional process etches sway areas of the layer positioned below the sacrificial material at places not covered by the sacrificial material.

19. A method to reduce line edge roughness in a semiconductor device, the method comprising:
providing a semiconductor substrate having a sacrificial material;
annealing the semiconductor substrate to reduce the line edge roughness of the sacrificial material;
performing at least one additional process to change a layer positioned below the sacrificial material; and
removing substantially all of the sacrificial material.

20. The method of claim 19, wherein the sacrificial material comprises silicon oxide.

21. The method of claim 19, wherein the annealing is performed using a sub-second anneal.

22. The method of claim 19, wherein the at least one additional process etches away areas of the layer positioned below the sacrificial material at places not covered by the sacrificial material.

23. A method comprising:
providing a semiconductor substrate including spacer material deposited as a part of a spacer-based double patterning (SBDP) process;
annealing the semiconductor substrate to change a characteristic of the spacer material;
etching a layer positioned below the spacer material; and
removing all or substantially all of the spacer material.

24. The method of claim 23, wherein the spacer material comprises a non-metallic material.

25. The method of claim 23, wherein the annealing is performed using a sub-second anneal.

26. The method of claim 23, wherein the annealing is performed using a flash lamp.

27. The method of claim 23, wherein the characteristic of the spacer material that is changed by the annealing is line edge roughness.

28. The method of claim 23, wherein the characteristic of the spacer material that is changed by the annealing is density.

29. The method of claim 23, wherein the characteristic of the spacer material that is changed by the annealing is a dimension.

30. The method of claim 23, further comprising providing a gas or a plasma at a surface of the semiconductor substrate during the annealing;
wherein the characteristic of the spacer material that is changed by the annealing is a chemical composition of a surface of the spacer material.
